(19) United States
(12) Patent Application Publication
(10) Pub. No.: US 2013/0081863 A1
(43) Pub. Date: Apr. 4, 2013

(54) SUBSTRATE WITH BUILT-IN ELECTRONIC COMPONENT AND METHOD FOR MANUFACTURING THE SAME

(71) Applicants: Doo Hwan LEE, Gyeonggi-do (KR); Tae Sung JEONG, Gyeonggi-do (KR); Jin Won LEE, Gyeonggi-do (KR); Moon Il KIM, Gyeonggi-do (KR)

(72) Inventors: Doo Hwan LEE, Gyeonggi-do (KR); Tae Sung JEONG, Gyeonggi-do (KR); Jin Won LEE, Gyeonggi-do (KR); Moon Il KIM, Gyeonggi-do (KR)

(73) Assignee: Samsung Electro-Mechanics Co., Ltd., Suwon (KR)

(21) Appl. No.: 13/607,971

(22) Filed: Sep. 10, 2012

(30) Foreign Application Priority Data
Sep. 30, 2011 (KR) 10-2011-0100220

(51) Int. Cl. H05K 1/16; H05K 3/10; H05K 1/09

(52) U.S. Cl. 174/257; 174/260; 156/280; 156/250; 156/268

(57) ABSTRACT

Provided are a substrate with built-in electronic component and a method for manufacturing the same. The method for manufacturing a substrate with built-in electronic component includes: forming conductive temporary bumps which penetrate and protrude through a prepreg sheet; mounting and attaching an electronic component on the protruding temporary bumps; forming an embedded substrate by laminating other prepreg sheet on the attached electronic component layer, laminating a metal sheet on a bottom of a laminate or on a bottom and top of the laminate, and pressing the prepreg sheets and the metal sheet; forming contact grooves by removing partial regions of the metal sheet and by removing the temporary bumps exposed by the removal of the metal sheet regions; and filling the contact grooves with a conductive metal and forming a circuit pattern.

### CROSS-REFERENCE TO RELATED APPLICATIONS

This application claims the benefit of Korean Patent Application No. 10-2011-0100220 filed with the Korea Intellectual Property Office on Sep. 30, 2011, the disclosure of which is incorporated herein by reference.

### BACKGROUND OF THE INVENTION

1. Field of the Invention

The present invention relates to a substrate with built-in electronic component and a method for manufacturing the same. In particular, the present invention relates to a substrate with built-in electronic component and a method for manufacturing the same, in which a process of connecting the electronic component and a substrate circuit is simplified.

2. Description of the Related Art

As a variety of electronic devices such as a mobile device have been made smaller and slimmer, wiring substrates used in the electronic devices and electronic components mounted thereon have also been made smaller. In addition, high density package has been in progress. Substrates with built-in electronic component have recently been developed. Since electronic components are embedded in substrates, an extra surface area may be secured. Therefore, multi functions may be provided, and it is possible to expect high frequency low loss/high efficiency and miniaturization according to minimization of a signal transfer path.

The competitiveness of substrates with built-in electronic component needs to be considered in terms of substrate processes, such as diversity of part electrode materials, capability of coping with fine pitches, practicality of yield and process, reliability, and a cost increase range, and in terms of customer value, such as design degree of freedom and electrical/mechanical performance improvement.

A conventional method for manufacturing a substrate with built-in electronic component will be described briefly.

Electronic components are mounted on a substrate during a substrate manufacturing process, and an insulating layer is laminated thereon so that the electronic components are embedded in the substrate. Then, via-holes are formed using a laser in order for electrical connection between the embedded electronic components and a substrate circuit. The via-holes are filled with a conductive material by a plating process. Interconnections of the substrate and external terminal electrodes of the electronic components are electrically connected to form circuit patterns.

Therefore, it is necessary to perform an additional process on the electrodes of the fine-pitch electronic components having general electrodes such as aluminum electrodes. To this end, electronic components having undergone an additional process such as redistribution and/or electrode arrangement by a wafer process have been embedded in a substrate.

There is a need for improving an additional process for electronic components in terms of cost and process.

### SUMMARY OF THE INVENTION

The present invention has been invented in order to overcome the above-described problems and it is, therefore, an object of the present invention to provide technology for embedding electronic components, capable of simplifying a process of connecting electronic components and a substitute circuit and reducing manufacturing costs.

In accordance with one aspect of the present invention to achieve the object, there is provided a method for manufacturing a substrate with built-in electronic component, which includes: forming conductive temporary bumps which penetrate and protrude through a prepreg sheet; mounting and attaching an electronic component on the protruding temporary bumps; forming an embedded substrate by laminating other prepreg sheet on the attached electronic component layer, laminating a metal sheet on a bottom of a laminate or on a bottom and top of the laminate, and pressing the prepreg sheets and the metal sheet; forming contact grooves by removing partial regions of the metal sheet and by removing the temporary bumps exposed by the removal of the metal sheet regions; and filling the contact grooves with a conductive metal and forming a circuit pattern.

The step of forming the temporary bumps may include forming the conductive temporary bumps penetrating and protruding through via-holes formed in the prepreg sheet.

In the step of forming the temporary bumps, a conductive paste may be screen printed on the prepreg sheet and penetrate through the via-holes to protrude, or the conductive temporary bumps may be fixed to a jig and penetrate through the via-holes to protrude.

In the step of forming the temporary bumps, the conductive temporary bumps tapered toward an end thereof may be fixed to a jig and penetrate through the prepreg sheet to protrude.

The electronic component may be attached by pressurizing the electronic component mounted on the protruding temporary bumps, or heating the temporary bumps, or by pressurizing the mounted electronic component and heating the temporary bumps.

The electronic component may include a chip part with a plurality of electrode pads, the electrode pads may be attached on the temporary bumps, and the electrode pads may include any one of aluminum (Al), nickel (Ni), copper (Cu), and aluminum (Au).

The step of forming the embedded substrate may include: laminating the metal sheet on the bottom of the laminate or on the bottom and top of the laminate, and pressing the metal sheet; and cutting the resulting structure to form the embedded substrate.

The electronic component may include a chip part with a plurality of electrode pads, and the step of forming of the contact grooves may include: removing partial regions of the metal sheet; and forming the contact grooves by performing a laser process or a desmear process to remove the temporary bumps exposed in the removed regions corresponding to at least electrode pad positions of the chip part.

The laser process or the desmear process may be performed to remove the temporary bumps such that a residue of the temporary bump partially remains on at least a surface contacting the electrode pad among inner surfaces forming the contact groove.

The residue of the temporary bump partially may remain on the surface contacting the electrode pad and the side walls forming the contact groove.

The step of forming the contact grooves may further include forming a contact groove(s) by performing the laser process to remove the temporary bump(s) exposed in the removed region(s) except the electrode pad positions of the chip part after removing the partial regions of the metal sheet, and the temporary bumps exposed in the removed regions corresponding to the electrode pad positions of the chip part may be removed by the desmear process.

The removed regions removed in the step of removing the partial regions of the metal sheet may include regions corresponding to the temporary bump positions and a region(s) being out of the temporary bumps, and the step of forming the contact groove(s) in the removed region(s) except the electrode pad positions of the chip part may further include forming contact groove(s) contacting conductive pad(s) of the electronic component except the chip part by removing the pressed prepreg sheet layer, which is exposed in the region(s) being out of the temporary bump positions, of the embedded substrate formed by the press process.

The conductive metal filling the contact grooves may include copper (Cu).

In accordance with another aspect of the present invention to achieve the object, there is provided a method for manufacturing a substrate with built-in electronic component, which includes: forming conductive bumps penetrating and protruding through a prepreg sheet; mounting an electronic component on the protruding conductive bumps and attaching conductive pads of the electronic component and the conductive bumps; forming an embedded substrate by laminating other prepreg sheet on the attached electronic component layer, laminating a metal sheet on a bottom of a laminate or on a bottom and top of the laminate, and pressing the prepreg sheets and the metal sheet; forming a contact groove(s) by removing a partial region(s) of the metal sheet and by removing the pressed prepreg sheet layer of the embedded substrate exposed by the removal of the metal sheet region(s); and filling the contact groove(s) with a conductive metal and forming a circuit pattern

The conductive pads and the conductive bumps may be attached by heating the conductive bumps and pressurizing the electronic component mounted on the conductive bumps.

The step of forming the contact groove(s) may include: removing the partial region(s) of the metal sheet which is out of the conductive bump positions; and performing a laser process to remove the prepreg sheet layer of the embedded substrate exposed in the region(s) being out of the conductive bumps, and forming the contact groove(s) contacting other conductive pad(s) of the electronic component.

The conductive bumps and the conductive metal filling the contact groove(s) may include copper (Cu).

In accordance with another aspect of the present invention to achieve the object, there is provided a substrate with built-in electronic component, which includes: an electronic component with a plurality of electrode pads; a pressed prepreg layer formed by pressing insulating prepreg sheets to surround the electronic component, wherein contact grooves contacting the electrode pads of the electronic component from the outside of the pressed sheet layer are formed; a first conductive material partially remaining on at least a surface contacting the electrode pad among inner surfaces forming the contact groove according that temporary bumps formed by the first conductive material are removed to form the contact grooves in the pressed prepreg layer; a second conductive metal filling the contact grooves; and a circuit pattern formed on a bottom of the pressed prepreg layer or on a bottom and top of the pressed prepreg layer and made of the same material as the second conductive metal.

A material of the electrode pads may include any one material of aluminum (Al), nickel (Ni), copper (Cu), and gold (Au), the first conductive material may include aluminum (Al) or copper (Cu), and the second conductive material may include copper (Cu).

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIGS. 1A to 1F are schematic views showing a method for manufacturing a substrate with built-in electronic component in accordance with an embodiment of the present invention;

FIGS. 2A to 2C are detailed views showing a process of FIG. 1A in accordance with an embodiment of the present invention;

FIGS. 3A to 3C are detailed views showing a process of FIG. 1B in accordance with an embodiment of the present invention; and

FIGS. 4A to 4C are detailed views showing a process of FIG. 1E in accordance with an embodiment of the present invention.

### DETAILED DESCRIPTION OF THE PREFERABLE EMBODIMENTS

Embodiments of the present invention for achieving the above objects will be described with reference to the accompanying drawings. In the specification, like reference numerals denote like elements, and duplicate or redundant descriptions will be omitted for conciseness.

It will be understood that when an element is referred to as being ‘connected to’ or ‘coupled to’ another element, it may be directly connected or coupled to the other element or at least one intervening element may be present therebetween. In contrast, when an element is referred to as being ‘directly connected to’ or ‘directly coupled to’ another element, there are no intervening element therebetween. Spatially relative terms, such as “above,” “upper,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features.

It should be noted that the singular forms ‘a’ ‘an’ and ‘the’ are intended to include the plural forms as well, unless the context clearly indicates otherwise. It should be understood that the terms ‘comprise’, ‘include’ and ‘have’, when used in this specification, specify the presence of stated features or elements, but do not preclude the presence or addition of one or more other features, elements, or combinations thereof.

The accompanying drawings are ideal or abstract illustrations for describing the embodiments of the present invention, in which structural features such as shape, size and thickness may be exaggerated for effective description of technical features.

First, a method for manufacturing a substrate with built-in electronic component in accordance with a first embodiment of the present invention will be described in detail with reference to the accompanying drawings.

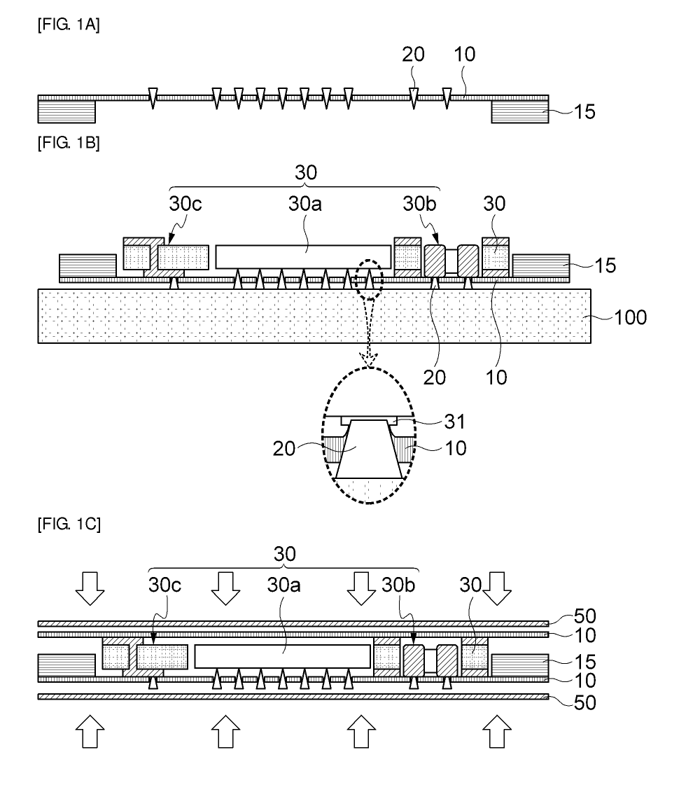

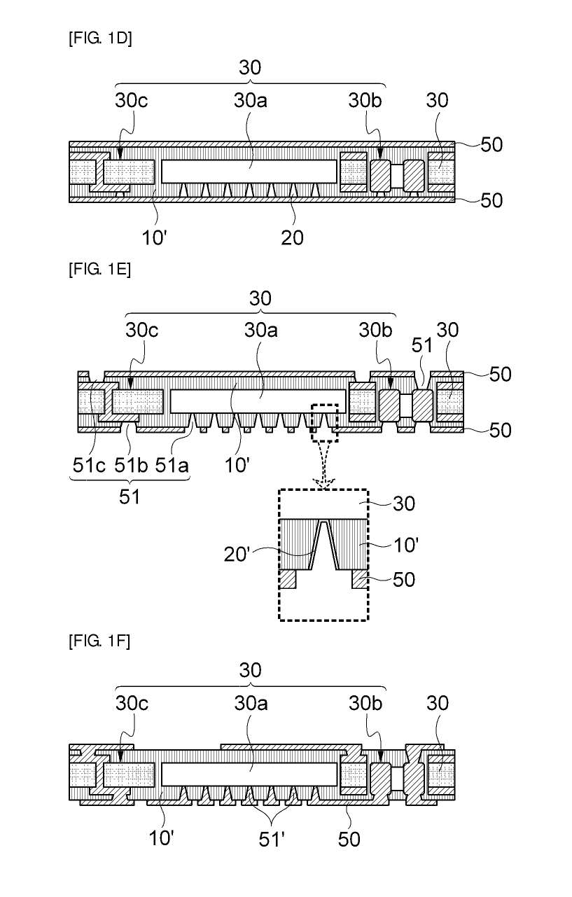

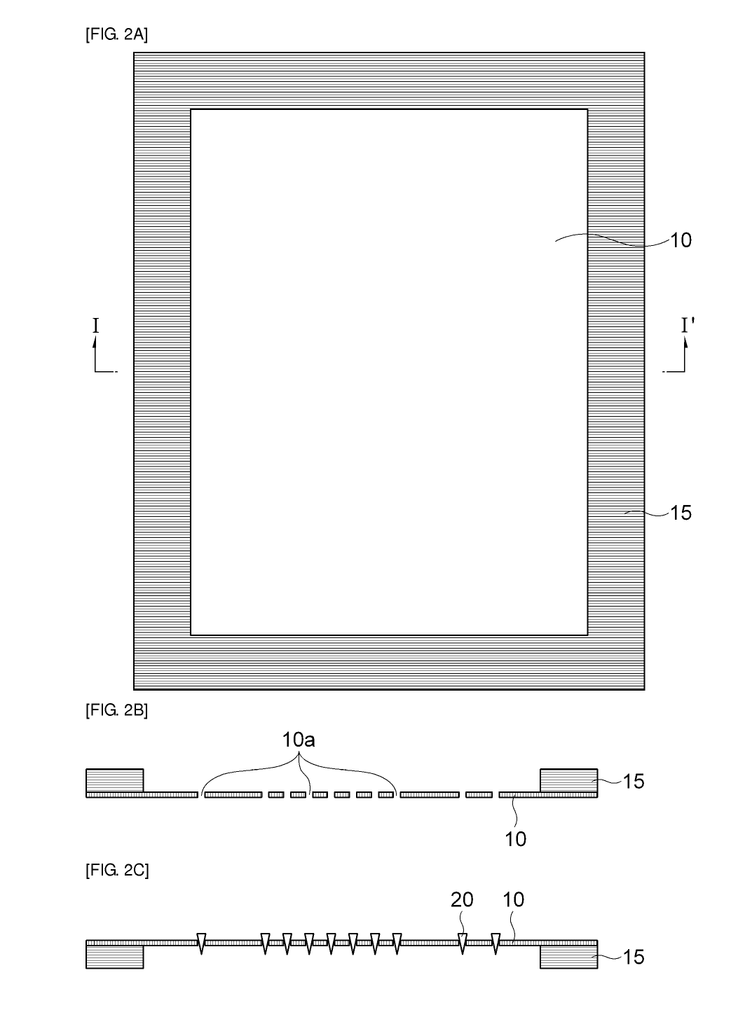

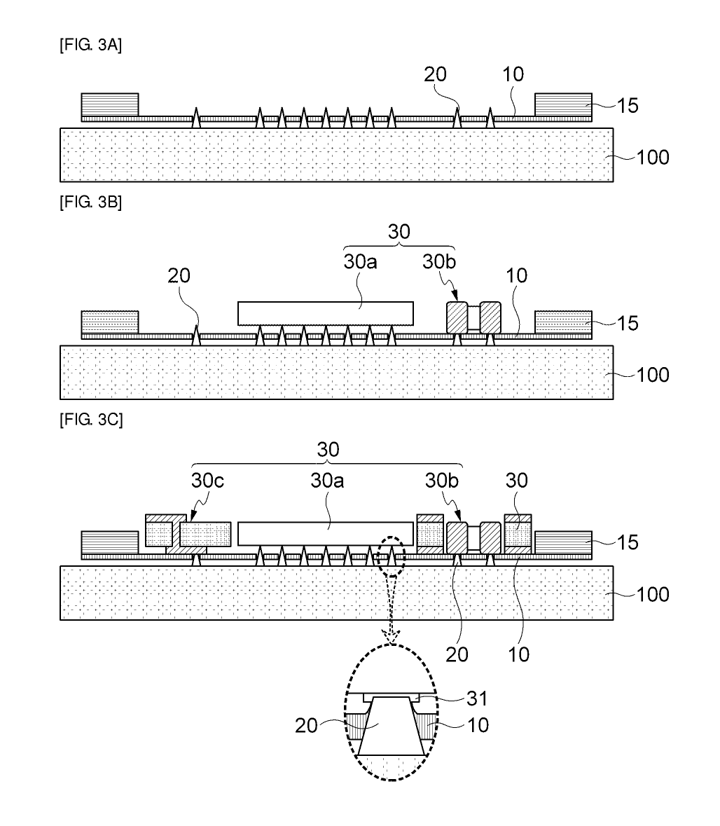

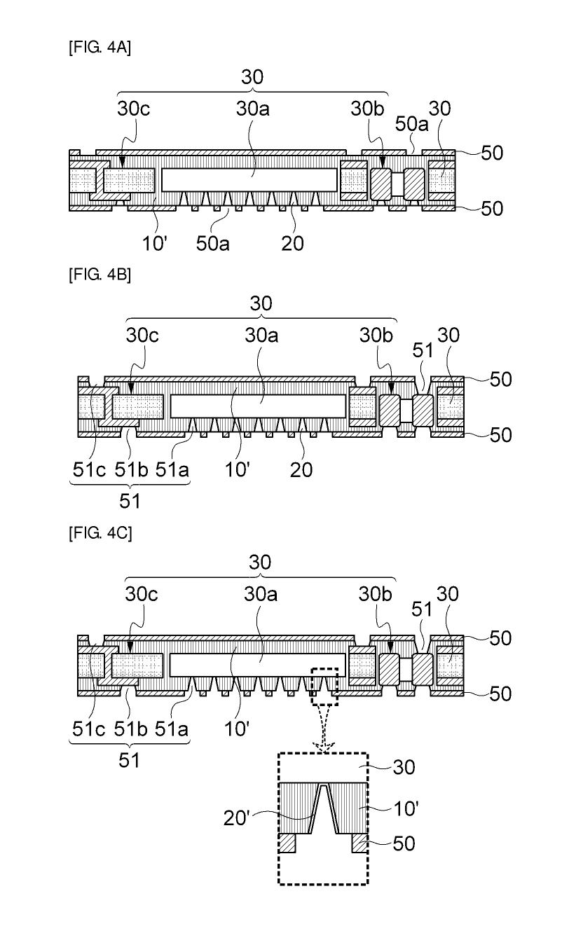

FIGS. 1A to 1F are schematic views showing a method for manufacturing a substrate with built-in electronic component in accordance with an embodiment of the present invention. FIGS. 2A to 2C are detailed views showing a process of FIG. 1A in accordance with an embodiment of the present invention. FIGS. 3A to 3C are detailed views showing a process of FIG. 1B in accordance with an embodiment of the present invention. FIGS. 4A to 4C are detailed views showing a process of FIG. 1E in accordance with an embodiment of the present invention.

Referring to FIGS. 1A to 1F, a method for manufacturing a substrate with built-in electronic component in accordance with an embodiment of the present invention includes forming temporary bumps 2 (see FIG. 1A), mounting and attaching an electronic component 30 on the temporary bumps 20 (see FIG. 1B), forming an embedded substrate (see FIGS. 1C and 1D), forming contact grooves 51 (see FIG. 1E), and forming circuit patterns 50′ (see FIG. 1F). In the description of the current embodiment, the reference numerals referring to the respective elements may be shown in other drawings even if they are not present in a corresponding drawing.

Referring to FIG. 1A, conductive temporary bumps 20 penetrating through a prepreg sheet 10 and protruding are formed. The prepreg is an intermediate material for a reinforced fiber composite material. For example, the prepreg is a material prior to a lamination molding of an interlayer insulating material in a printed circuit board (PCB). In one example, the prepreg sheet 10 has insulating properties. For example, the material of the prepreg sheet 10 may include any one of a B-stage resin, an epoxy, and a glass fabric. The prepreg sheet 10 is pressed in a subsequent process to form an insulating layer 10′. In accordance with an embodiment of the present invention, the temporary bumps 20 are fixed by the prepreg sheet 10.

In one example, the conductive material forming the temporary bumps 20 is required to be electrically conductive even after thermal, chemical and physical attachment to conductive pads (31 in FIG. 1B) of the electronic component 30. In addition, if the conductive material forming the temporary bumps 20 is removed in step of forming the contact grooves 51, the conductive material partially remains on at least conductive pads surface of the electronic component 30, and the remaining residue (20′ in FIG. 1F) is required to have excellent attachment properties with a conductive metal (51′ in FIG. 1F) in step of forming circuit patterns (50′ in FIG. 1F). The conductive metal may include aluminum (Al), copper (Cu), or the like; however, the present invention is not limited thereto. Any known material may be used as long as it has the above-described physical properties.

Another embodiment of the present invention will be described below with reference to FIGS. 2A to 2C. In step of forming the temporary bumps 20 shown in FIG. 1A, conductive temporary bumps 20 may be formed to penetrate and protrude through via-holes 10a of the prepreg sheet 10. FIG. 2A shows the prepreg sheet 10 is tightly fixed by a jig 15, and FIG. 2B shows via-holes 10a formed in the prepreg sheet 10 fixed by the jig 15. The via-holes 10a may be formed in the prepreg sheet 10 by a laser or the like. In this case, the via-holes 10a are formed in a smaller size than the conductive pads 31 of the electronic component 30 such as a chip part 30a to be mounted on the temporary bumps 20. In addition, the via-holes 10a formed in the prepreg sheet 10 are determined by spacing of the electrode pads or conductive pads 31 of the electronic component 30 to be mounted on the temporary bumps 20. FIG. 2C shows the temporary bumps 20 penetrating and protruding through the via-holes 10a of the prepreg sheet 10.

As one example, the processes of FIGS. 2A to 2C may be performed in sequence. Although not shown, after the conductive material forming the temporary bumps 20 penetrates and protrudes through the prepreg sheet 10, it may fix the prepreg sheet 10 to the jig 15. The jig 15 for fixing the prepreg sheet 10 may be disposed above or under the prepreg sheet 10.

As other example, in step of forming the temporary bumps 20 in FIG. 1A or 2C, a conductive paste is screen printed on the prepreg sheet 10 and penetrates through the via-holes 10a to protrude, or the conductive temporary bumps 20 are fixed to a jig (not shown) and penetrate through the via-holes 10a to protrude. In this manner, the temporary bumps 20 may be formed. The conductive material is required to be easily fixed when contacting the electronic component 30 by either or both of a physical mechanism and a chemical mechanism with the electrode pads (31 in FIG. 1B) of the electronic component (30 in FIG. 1B), for example, an electrode pads made of Al or Cu, or an under bump metallization (UBM).

The temporary bumps 20 made of the conductive material does not remain in a final product step and may be replaced by plating a conductive metal (e.g., Cu) having excellent conductive properties. Meanwhile, the conductive material forming the bumps may remain without replacing the bumps made of a conductive material in a final product step, only if the conductive material has no problem in the conductive properties. This will be described below in a second embodiment of the present invention.

Although not shown, in accordance with another embodiment of the present invention, in step of forming the temporary bumps 20 of FIG. 1A, conductive temporary bumps 20 tapered toward the end thereof may be fixed to the jig 15 and penetrate through the prepreg sheet 10 to protrude. In this case, it is unnecessary to separately process the via-holes 10a on the prepreg sheet 10.

Referring to FIG. 1B, the electronic component 30 is mounted on the protruding temporary bumps 20. In this step, conductive pads 31 of the electronic component 30 are attached to the protruding temporary bumps 20. As one example, the electronic component 30 may include a chip part 30a with a plurality of electrode pads 31. Furthermore, the electronic component 30 mounted on the temporary bumps 20 may include passive elements 30b or a substrate 30c with via-holes holes or circuit patterns, as well as the chip part 30a. In this case, a region of the electronic component 30 coming into contact with the temporary bumps 20 may be conductive pads 31. The conductive pads may include electrode pads or UBM of the chip part 30a or the passive element 30b, and circuit patterns formed above and/or under the substrate 30c as the electronic component 30. Moreover, the circuit patterns formed above and/or under the substrate 30c as the electronic component 30 may be a single electrode pads as well as the conductive pads 31. As one example, in the case of the chip part 30a, the electrode pads 31 of the chip part 30a are attached to the temporary bumps 20. As another example, the electrode pads 31 of the chip part 30a may include aluminum (Al), nickel (Ni), copper (Cu), gold (Au), or the like.

Step of mounting and attaching the electronic component 30 of FIG. 1B will be described in more detail with reference to FIGS. 3A to 3C. Referring to FIG. 3A, the prepreg sheet 10, to which the jig 15 of FIG. 1A or 2C is fixed and in which the temporary bumps 20 are formed, is prepared on a substrate holder 100. A release agent may be coated on the bottom of the temporary bumps 20 and the prepreg sheet 10 may be placed on the substrate holder 100. Also, the prepreg sheet 10 may be placed on the substrate holder 100, without regard to the adhesive force of the temporary bumps 20. Referring to FIG. 3B, the electronic component 30 is mounted on the temporary bumps 20. In FIGS. 3B and 3C, reference numeral 30a represents a chip part as an example of the electronic component 30, and reference numeral 30b represents a passive element as an example of the electronic component 30. The passive element 30b may be mounted in an internal electrode (typically, Ni, Pd or Cu paste) state, instead of an external electrode of TiN plating, or a Cu-plated external electrode state, instead of an electrode necessary for soldering. Therefore, the electrode may contact the temporary bumps 20. In addition, the electronic component 30 may be mounted in a state that only the electrode paste made of Cu remains. In this case, a subsequent plating process may be performed. Reference numeral 30c represents a substrate in which via-holes holes are formed as an example of the electronic component 30. Referring to FIG. 3C, the temporary bumps 20 and the lower conductive pads or electrode pads 31 of the mounted electronic component 30 are attached by either or both of pressurization and heating.

Another embodiment of the present invention will be described below with reference to referring to FIG. 3C. In step of mounting and attaching the electronic component 30 of FIG. 1B, the electronic component 30 mounted on the protruding temporary bumps 20 may be attached by heating the temporary bumps 20 or by pressurizing the mounted electronic component 30 and heating the temporary bumps 20. For example, in the case of the heating, the prepreg sheet 10 is also heated to attach the temporary bumps 20 so that a portion thereof is fixed.

Next, referring to FIGS. 1C and 1D, other prepreg sheet 10 is laminated on the attached electronic component layer. A metal sheet 50 is laminated on the bottom of the sheet laminate or on the top and bottom of the sheet laminate, and an embedded substrate is formed by pressing the resulting structure. In this case, circuit patterns (50′ in FIG. 1F) are formed in the metal sheet 50 in a final product step. In addition, during this process, the prepreg sheets 10, which of one is used to fix the temporary bumps 20 and other is laminated on the electronic component layer, are pressed and heated to melt down between the electronic components 30a, 30b and 30c. The prepreg sheet 10 is used to fix the temporary bumps 20 and remains in a final product, without being removed, to thereby form an insulating layer 10′. In one example, a metal sheet 50 may be laminated on the top and bottom of the laminate in which other prepreg sheet 10 is laminated on the electronic component layer. In another example, the metal sheet 50 may be laminated on only the bottom of the laminate in which other prepreg sheet 10 is laminated on the electronic component layer, and only an insulating layer (not shown) may be laminated on the laminate.

An embodiment of the present invention will be described below with reference to FIGS. 1C and 1D. Step of forming the embedded substrate may include laminating a metal sheet 50 on the bottom of the laminate or on the top and bottom of the sheet laminate and pressing the metal sheet 50 (see FIG. 1C), and forming the embedded substrate by cutting the metal sheet 50 after the pressing process (see FIG. 1D). Referring to FIG. 1C, in step of laminating and pressing the metal sheet 50, a vertical pressure may be applied and simultaneously the laminate may be heated. Referring to FIG. 1D, the prepreg sheet is processed into an insulating layer 10′ after the pressing process. Then, a routing process is performed to cut the inside of the jig 15 fixing the prepreg sheet. In this manner, the electronic component 30 is built in the substrate.

Next, referring to FIG. 1E, the partial regions of the metal sheet 50 are removed. In FIG. 4A, reference numeral 50a represents the removed regions of the metal sheet 50. The exposed temporary bumps 20 according to the metal sheet removing process and the temporary bumps removing process are removed. As a result, contact grooves 51 are formed. The contact grooves 51 serve to connect the circuit patterns (50′ in FIG. 1F) of the final product and the conductive pads or electrode pads 31 of the electronic component 30.

Step of forming the contact grooves 51 of FIG. 1E will be described below in more detail with reference to FIGS. 4A to 4C. The electronic component 30 includes a chip part 30a with a plurality of electrode pads 31. Referring to FIGS. 4A to 4C, step of forming the contact grooves 51 of FIG. 1E may include removing partial regions of the metal sheet (reference numeral 50a represents the removed regions of the metal sheet) (see FIG. 4A), and forming contact grooves 51, 51a and 51b by performing a laser process or a desmear process to remove the temporary bumps 20 exposed in the removed portion 50a corresponding to at least electrode pad positions of the chip part 30a (see FIG. 4C). The temporary bumps 20 are removed so as to increase current transfer efficiency by replacing the temporary bumps 20 with a conductive metal (51′ in FIG. 1F) having more excellent conductive properties than the temporary bumps 20. The partial regions of the metal sheet may be removed by laser skiving or window open exposure process.

Specifically, referring to FIG. 4A, the partial regions of the metal sheet where the contact grooves 51 are to be formed may be removed (reference numeral 50 represents the removed regions of the metal sheet). The region where the contact grooves 51, 51a and 51b are to be formed may be a region corresponding to the temporary bump positions. In one example, as shown in FIG. 4A, the metal sheet 50 may be removed from the region(s) corresponding to the position(s) deviated from the temporary bumps 20, for example, the partial region(s) of the upper metal sheet in FIG. 4A, as well as the temporary bump positions. The metal sheet may be removed by laser skiving or window open exposure process. In the case of the laser skiving, the metal sheet region may be peeled using YAG laser. In addition, in the case of the exposure process, the metal sheet region may be removed using a method that is commonly used in semiconductor technology. For example, in the case where the partial regions of the metal sheet are removed by the laser skiving or window open exposure process, a portion of the temporary bumps 20 may be processed.

Referring to FIG. 4C, the contact grooves 51a are formed by removing the temporary bumps 20 exposed in the regions corresponding to at least the electrode pad positions of the chip part 30a in the regions 50a where the metal sheet is removed. In this case, the exposed temporary bumps 20 may be removed by a laser process or a desmear process. As one example, the temporary bumps 20 exposed in the regions corresponding to at least the electrode pad positions of the chip part 30a may be removed by a desmear process. In the case where the desmear process is performed, electrical properties of the product may be further improved by filling the contact grooves 51a, which are formed by chemically removing the temporary bumps 20, with a conductive metal (51′ in FIG. 1F) by a plating process. In this case, roughness is formed by leaving the residue 20′ of the thin temporary bumps in the inner wall of the contact grooves 51a during the desmear process. Therefore, adhesion may be improved by the subsequent plating of the conductive metal (51′ in FIG. 1F).

Referring to FIG. 1E or 4C, the temporary bumps 20 may be removed such that the residue 20′ of the temporary bump partially remains on at least the surface contacting the electrode pad 31 among the inner surfaces forming the contact grooves 51 or 51a in the laser process or the desmear process. Accordingly, the contact between the conductive metal (51′ in FIG. 1F) and the electrode pads 31 may be reinforced in a subsequent process. In this case, as one example, the residue 20′ may remain at a thickness of several micrometers or more in order that it cannot be vaporized during the laser process. In the case where the residue 20′ remains at a thickness of several micrometers or more, it can withstand the plating when the conductive metal (51′ in FIG. 1F) is plated in a subsequent process. As one example, a paste of a conductive material forming the temporary bumps 20 may be contacted with an interface by a thermochemical reaction on the surface of the electrode pads (31 in FIG. 1B) of the electronic component 30, and the temporary bumps 20 except the remaining temporary bumps 20′ on the other contact interface may be removed. The space may be filled with a conductive material (51′ in FIG. 1F) having high conductivity by a plating process. As one example, adhesion on the contact interface may be increased by a mechanical or thermal pressurization process during contacting the electronic component 30. Therefore, in the process of removing the temporary bumps, the residue 20′ of the temporary bumps 20 may be left on at least the contact interface.

Furthermore, as shown in FIGS. 1E and 4C, the conductive residue 20′ of the temporary bumps 20 may partially remain on the surface contacting the electrode pad 31 and the side walls forming the contact grooves 51 and 51a. In addition, as one example, the residue 20′ may remain on the inner walls of the contact grooves 51 and 51a at a thickness of several micrometers.

Step of forming the contact grooves 51 of FIG. 1E will be described below in more detail with reference to FIGS. 4A to 4C. Step of forming the contact grooves 51 of FIG. 1E may include removing partial regions of the metal sheet (see FIG. 4A), and forming a contact groove(s) 51b by removing the temporary bump(s) 20 exposed in the removed region(s) 50a except the electrode pad positions of the chip part 30a by a laser process (see FIG. 4B). FIG. 4B shows the removal of the temporary bump(s) 20 except the regions corresponding to the electrode pad positions of the chip part 30a after the removal of the metal sheet regions where the temporary bumps 20 are formed at a lower portion in FIG. 4A. As one example, referring to FIG. 4C, the temporary bumps 20 exposed in the regions 50a corresponding to the electrode pad positions of the chip part 30a may be removed by a desmear process, thereby forming the contact grooves 51 and 51a.

Referring to FIGS. 4A and 4B, the region 50a removed in step of removing partial regions of the metal sheet may include a region corresponding to the temporary bump positions, and a region(s) being out of the temporary bump positions. FIG. 4A shows the regions in which the lower temporary bumps 20 are exposed and the regions which are out of the upper temporary bump positions, in the removed regions 50a of the metal sheet. Referring to FIG. 4B, as one example, step of forming the contact groove in the removed region(s) except the electrode pad positions of the chip part 30a may further include forming the contact groove(s) 51c contacting the conductive pad(s) (refer to 31 in FIG. 1B) of the electronic component 30b or/and 30c except the chip part 30a by removing the pressed prepreg sheet layer of the embedded substrate formed by the pressing process and exposed in the region(s) being out of the temporary bump positions. A lower portion of FIG. 4B shows the contact groove(s) 51b formed as a result of removing the temporary bump(s) 20 in the region(s) corresponding to the temporary bump position(s) except the electrode pad positions of the chip part 30a. An upper portion of FIG. 4B shows the contact groove(s) 51c formed as a result that the prepreg sheet layer of the embedded substrate is removed in the region(s) being out of the temporary bump positions.

Referring to FIG. 1F, the contact grooves 51 are filled with a conductive metal 51′, and circuit patterns 50′ are formed. As one example, the conductive metal 51′ filling the contact grooves 51 may be made of the same material as the metal sheet 50 laminated in the pressing step of FIG. 1C. As one example, the contact grooves 51 may be filled with the conductive metal 51′ by a plating process or other processes. For example, in this step, the substrate with built-in electronic components may be completed by the process of plating the conductive metal 51′ on the contact grooves 51 and the process of forming circuit patterns 50′.

More specifically, the conductive metal 51′ filling the contact grooves 51 may include Cu.

In accordance with an embodiment of the present invention, a part of subsequent wafer processes such as redistribution may be skipped. In the case of passive components to be embedded in the substrate, the final surface plating may be in a paste state. In the case of the chip part, Al electrode pads or wirebonding (W/B) pad may be used. Therefore, the unit cost of the electronic component to be embedded in the substrate may be reduced. In addition, as one example, tolerance may be eliminated by a laser process. When assuming that a via-holes size is at least 50 um, processability to I/O having a pitch of about 100 um may be increased.

Next, a method for manufacturing a substrate with built-in electronic component in accordance with a second embodiment of the present invention will be described below with reference to FIGS. 1A to 1F. It should be noted that, instead of the temporary bumps 20, the bump connecting the circuit patterns 50′ and the electrode pads (31 in FIG. 1B) of the electronic component 30 is used in the final product step. In addition, unlike the case shown in FIG. 1E, the prepreg sheet layer of the embedded substrate is partially removed in order to form a contact groove(s) for connection to the electronic component 30 only in the region(s) except the regions where the temporary bumps 20 are formed, for example, the upper portion of FIG. 1E.

The method for manufacturing the substrate with built-in electronic component In accordance with an embodiment of the present invention includes forming conductive bumps, attaching the conductive bumps to conductive pads 31 of the electronic component 30, forming an embedded substrate, forming a contact groove(s), and forming a circuit pattern 50′.

Unlike the case shown in FIG. 1A, the conductive bumps, instead of the temporary bumps, are formed at the temporary bump positions. At this time, it may be understood that reference numeral 20 of FIG. 1A refers to the conductive bumps. That is, the conductive bumps are formed to penetrate and protrude through the prepreg sheet 10. The details can be understood by referring to the process of forming the temporary bumps in the first embodiment described above. However, it should be noted that the conductive bumps remaining even in the final product step is used, instead of the temporary bumps.

Referring to FIG. 1B, the conductive bumps 20, instead of the temporary bumps, are mounted on the electronic component 30. That is, the electronic component 30 is mounted on the protruding conductive bumps, and the conductive pads 31 of the electronic component 30 are attached to the conductive bumps. The details can be understood by referring to the process of mounting and attaching the electronic component 30 in the first embodiment described above. The electronic component 30 may be mounted on and attached to the conductive bumps remaining even in the final product step, instead of the temporary bumps. It may be understood that reference numeral 20 of FIG. 1B represents the conductive bumps.

Referring to FIGS. 1C and 1D, other prepreg sheet 10 is laminated on the attached electronic component layer, and the metal sheet 50 is laminated on the bottom of the laminate or on the top and bottom of the laminate. The laminated structure is pressed to form an embedded substrate. The details may be understood from the first embodiment described above. However, it should be noted that the conductive bumps remaining even in the final product step is applied in FIGS. 1C and 1D, instead of the temporary bumps.

In accordance with another embodiment, the conductive pads 31 and the conductive bumps may be attached by heating the conductive bumps and pressurizing the electronic component 30 mounted on the protruding conductive bumps.

Then, partial regions of the metal sheet are removed (refer to 50a in an upper portion of FIG. 4A). In addition, the prepreg sheet layer of the embedded substrate exposed by the removal of the metal sheet regions is removed. As a result, a contact groove(s) 51c (refer to 50c in an upper portion of FIG. 4B) is formed. Unlike the case shown in FIG. 1E, this process is performed by removing the prepreg sheet layer of the embedded substrate in order to form the contact groove(s) 51c for connection to the electronic component 30 only in the region(s) except the temporary bump positions, for example, the upper portion of FIG. 4B.

In addition, step of forming the contact groove(s) 51c may include: removing partial region(s) of the metal sheet which is out of the conductive bump positions (see 50a shown in the upper portion of FIG. 4a); and performing a laser process to remove the prepreg sheet layer of the embedded substrate exposed in the region(s) being out of the conductive bump positions, and forming the contact groove(s) 51c contacting other conductive pads (refer to 31 in FIG. 1B) of the electronic component 30. In this case, the partial regions of the metal sheet which are out of the conductive bump positions may be removed by laser skiving or window open exposure process.

Then, referring to FIG. 1F, the contact groove(s) 51c is filled with a conductive metal 51′ and circuit patterns 50′ are formed. In this embodiment, since the conductive bumps remaining in the final step are disposed at the position where the temporary bumps 20 are formed as shown in FIGS. 1A to 1D, the contact groove(s) 51c filled with the conductive metal 51′ is limited to the contact groove(s) 51c for connection between the electronic component 30 and the final circuit patterns 50′ at the position where the conductive bumps are not disposed.

In accordance with another embodiment of the present invention, the conductive bumps and the conductive metal 51′ filling the contact groove(s) 51c may include Cu.

Next, a substrate with built-in electronic component in accordance with a third embodiment of the present invention will be described with reference to the accompanying drawing. FIG. 1F schematically shows the substrate with built-in electronic component in accordance with an embodiment of the present invention.

Referring to FIG. 1F, the substrate with built-in electronic component includes an electronic component 30, a pressed prepreg layer 10′, a first conductive material (20′ in FIG. 1E), and a circuit pattern 50′.

In this embodiment, the electronic component 30 includes a chip part 30a with a plurality of electrode pads (31 in FIG. 1B). In addition, as one example, the material of the electrode pads (31 in FIG. 1B) may include Al, Ni, Cu, and Au.

The pressed prepreg layer 10′ is formed by pressing insulating prepreg sheets (10 in FIG. 1C) to surround the electronic component 30. The pressed prepreg layer 10′ has contact grooves (51 in FIG. 1E) contacting the electrode pads (31 in FIG. 1B) of the electronic component 30 from the outside of the pressed sheet layer.

The first conductive material (20′ in FIG. 1E) is partially removed after forming the temporary bumps (20 in FIGS. 1A to 1D) so as to form the contact grooves (51 in FIG. 1E) on the pressed prepreg layer. A portion of the first conductive material remains on at least the surface contacting the electrode pad (31 in FIG. 1B) among the inner surfaces forming the contact groove (51 in FIG. 1E). In addition, as one example, the first conductive material (20′ in FIG. 1E) may include Al or Cu.

The second conductive metal 51′ fills the contact grooves (51 in FIG. 1E). In addition, as one example, the second conductive material may include Cu.

The circuit pattern 50′ is formed on the bottom of the pressed prepreg layer 10′ or on the bottom and top of the pressed prepreg layer 10′. The circuit pattern 50′ is made of the same material as the second conductive metal 51′.

In accordance with embodiments of the present invention, the process for connecting the electronic component and the substrate circuit may be simplified, and the costs may be reduced.

That is, in accordance with embodiments of the present invention, the costs of the electronic components embedded in the substrate may be reduced. For example, a part of the subsequent wafer processes such as redistribution may be skipped. In the case of the passive components to be embedded in the substrate, the final surface electrode may be in a paste state, which is an internal electrode state, instead of plating. In addition, in the case of the chip part, Al electrode pads or wirebonding (W/B) pad may be used.

In addition, the embodiments of the present invention may be relatively free in fine pitch limitation. For example, tolerance may be reduced by laser process, and I/O may be processed.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

1. A method for manufacturing a substrate with built-in electronic component, which comprises:
forming conductive temporary bumps which penetrate and protrude through a prepreg sheet;
mounting and attaching an electronic component on the protruding temporary bumps;
forming an embedded substrate by laminating other prepreg sheet on the attached electronic component layer, laminating a metal sheet on a bottom of a laminate or on a bottom and top of the laminate, and pressing the prepreg sheets and the metal sheet;
forming contact grooves by removing partial regions of the metal sheet and by removing the temporary bumps exposed by the removal of the metal sheet regions; and
filling the contact grooves with a conductive metal and forming a circuit pattern.

2. The method according to claim 1, wherein the forming the temporary bumps comprises forming the conductive temporary bumps penetrating and protruding through via-holes formed in the prepreg sheet.

3. The method according to claim 2, wherein in the forming the temporary bumps, a conductive paste is screen printed on the prepreg sheet and penetrates through the via-holes to protrude, or the conductive temporary bumps are fixed to a jig and penetrate through the via-holes to protrude.

4. The method according to claim 1, wherein in the forming the temporary bumps, the conductive temporary bumps tapered toward an end thereof are fixed to a jig and penetrate through the prepreg sheet to protrude.

5. The method according to claim 1, wherein the electronic component is attached by pressurizing the electronic component mounted on the protruding temporary bumps, or heating the temporary bumps, or by pressurizing the mounted electronic component and heating the temporary bumps.

6. The method according to claim 1, wherein the electronic component comprises a chip part with a plurality of electrode pads, the electrode pads are attached on the temporary bumps, and the electrode pads comprise any one material of aluminum (Al), nickel (Ni), copper (Cu), and aluminum (Au).

7. The method according to claim 1, wherein the forming the embedded substrate comprises:
laminating the metal sheet on the bottom of the laminate or on the bottom and top of the laminate, and pressing the metal sheet; and
cutting the resulting structure to form the embedded substrate.

8. The method according to claim 1, wherein the electronic component comprises a chip part with a plurality of electrode pads, and
the forming of the contact grooves comprises:
removing partial regions of the metal sheet; and
forming the contact grooves by performing a laser process or a desmear process to remove the temporary bumps exposed in the removed regions corresponding to at least electrode pad positions of the chip part.

9. The method according to claim 8, wherein the laser process or the desmear process is performed to remove the temporary bumps such that a residue of the temporary bump partially remains on at least a surface contacting the electrode pad among inner surfaces forming the contact groove.

10. The method according to claim 9, wherein the residue of the temporary bump partially remains on the surface contacting the electrode pad and the side walls forming the contact groove.

11. The method according to claim 8, wherein the forming the contact grooves further comprises forming a contact groove(s) by performing the laser process to remove the temporary bump(s) exposed in the removed region(s) except the electrode pad positions of the chip part after removing the partial regions of the metal sheet, and
the temporary bumps exposed in the removed regions corresponding to the electrode pad positions of the chip part are removed by the desmear process.

12. The method according to claim 11, wherein the removed regions removed in the removing the partial regions of the metal sheet comprises a region corresponding to the temporary bump positions and a region(s) being out of the temporary bumps, and the step of forming the contact groove(s) in the removed region(s) except the electrode pad positions of the chip part further comprises forming contact groove(s) contacting conductive pad(s) of the electronic component except the chip part by removing the pressed prepreg sheet layer, which is exposed in the region(s) being out of the temporary bump positions, of the embedded substrate formed by the press process.

13. The method according to claim 1, wherein the conductive metal filling the contact grooves comprises copper (Cu).

14. A method for manufacturing a substrate with built-in electronic component, which comprises:
forming conductive bumps penetrating and protruding through a prepreg sheet;
mounting an electronic component on the protruding conductive bumps and attaching conductive pads of the electronic component and the conductive bumps;
forming an embedded substrate by laminating other prepreg sheet on the attached electronic component layer, laminating a metal sheet on a bottom of a laminate or on a bottom and top of the laminate, and pressing the prepreg sheets and the metal sheet;
forming a contact groove(s) by removing a partial region(s) of the metal sheet and by removing the pressed prepreg sheet layer of the embedded substrate exposed by the removal of the metal sheet region(s); and
filling the contact groove(s) with a conductive metal and forming a circuit pattern

15. The method according to claim 14, wherein the conductive pads and the conductive bumps are attached by heating the conductive bumps and pressurizing the electronic component mounted on the conductive bumps.

16. The method according to claim 14, wherein the forming the contact groove(s) comprises:
removing the partial region(s) of the metal sheet which is out of the conductive bump positions; and
performing a laser process to remove the prepreg sheet layer of the embedded substrate exposed in the region(s) being out of the conductive bumps, and forming the contact groove(s) contacting other conductive pad(s) of the electronic component.

17. The method according to claim 14, wherein the conductive bumps and the conductive metal filling the contact groove(s) comprise copper (Cu).

18. A substrate with built-in electronic component, which comprises:
an electronic component with a plurality of electrode pads;
a pressed prepreg layer formed by pressing insulating prepreg sheets to surround the electronic component, wherein contact grooves contacting the electrode pads of the electronic component from the outside of the pressed sheet layer are formed;
a first conductive material partially remaining on at least a surface contacting the electrode pad among inner surfaces forming the contact groove according that temporary bumps formed by the first conductive material are removed to form the contact grooves in the pressed prepreg layer;
a second conductive metal filling the contact grooves; and
a circuit pattern formed on a bottom of the pressed prepreg layer or on a bottom and top of the pressed prepreg layer and made of the same material as the second conductive metal.

19. The substrate according to claim 18, wherein a material of the electrode pads comprise any one material of aluminum (Al), nickel (Ni), copper (Cu), and gold (Au), the first conductive material comprises aluminum (Al) or copper (Cu), and the second conductive material comprises copper (Cu).
